(19) United States
(12) Patent Application Publication
(10) Pub. No.: US 2026/0333969 A1
(43) Pub. Date: Oct. 22, 2026

(54) DISPLAY DEVICE AND MANUFACTURING METHOD THEREOF

(71) Applicant: Innolux Corporation, Miaoli County (TW)

(72) Inventors: Yung-Hsin Lu, Miaoli County (TW); Jian-Min Leu, Miaoli County (TW); Yu-Shih Tsou, Miaoli County (TW); Yung-Hsun Wu, Miaoli County (TW)

(73) Assignee: Innolux Corporation, Miaoli County (TW)

(21) Appl. No.: 19/577,344

(22) Filed: Mar. 24, 2026

(30) Foreign Application Priority Data
Apr. 22, 2025 (CN) 202510508431.7

(51) Int. Cl. H10H 29/34; H10H 29/03

(52) U.S. Cl. CPC H10H 29/34; H10H 29/03

(57) ABSTRACT

A manufacturing method of a display device includes the following steps. An initial substrate is provided, wherein the initial substrate has a plurality of light-emitting elements thereon. A light wavelength characteristic value corresponding to each of the plurality of light-emitting elements is measured. The plurality of light-emitting elements are divided into a plurality of groups according to the corresponding light wavelength characteristic value, wherein the plurality of groups correspond to different light wavelength characteristic value intervals respectively. The light-emitting elements corresponding to each of the plurality of groups are transferred respectively. A circuit substrate is provided, and the plurality of groups of light-emitting elements are transferred onto the circuit substrate.

### CROSS-REFERENCE TO RELATED APPLICATION

This application claims the priority benefit of China application serial no. 202510508431.7, filed on Apr. 22, 2025. The entirety of the above-mentioned patent application is hereby incorporated by reference herein and made a part of this specification.

### BACKGROUND

### Technical Field

The disclosure relates to a display device and a manufacturing method thereof.

### Description of Related Art

As users have higher and higher requirements for the image quality of displays, micro LED displays are gradually becoming the mainstream display technique. In general, there are a plurality of micro LEDs on a wafer (also called chip on wafer; COW) or a plurality of micro LEDs on a carrier (also called chip on carrier; COC), and the plurality of micro LEDs are batch-transferred from the wafer or the carrier onto a circuit substrate in a matrix manner to form a micro LED display.

However, since the wavelengths of the same color light emitted by the plurality of micro LEDs on the wafer or the carrier are still different, after the plurality of micro LEDs of different regions of the wafer or the carrier are transferred to different regions of the circuit substrate, the micro LED display is prone to uneven color of a display block when displaying an image, or the phenomenon called mura, resulting in poor visual quality of the display. In order to effectively alleviate the above issue, micro LEDs having similar peak wavelengths and/or center wavelengths may be selected and transferred on a wafer or a carrier, or a specific driving method may be adopted to drive the micro LEDs. However, this will result in relatively low utilization of the micro LEDs on the wafer and/or reduce the color gamut area of the micro LED display.

### SUMMARY

The disclosure is directed to a manufacturing method of a display device that may reduce uneven color of a display block caused by mass transfer when displaying an image in the manufactured display device and/or improve the utilization rate of a plurality of light-emitting elements on an initial substrate.

A manufacturing method of a display device provided according to some embodiments of the disclosure includes the following steps. An initial substrate is provided, wherein the initial substrate has a plurality of light-emitting elements thereon. A light wavelength characteristic value corresponding to each of the plurality of light-emitting elements is measured. The plurality of light-emitting elements are divided into a plurality of groups according to the corresponding light wavelength characteristic value, wherein the plurality of groups correspond to different light wavelength characteristic value intervals respectively. The light-emitting elements corresponding to each of the plurality of groups are transferred respectively. A circuit substrate is provided, and the plurality of groups of light-emitting elements are transferred onto the circuit substrate.

The disclosure is directed to a display device that may reduce uneven color of a display block caused by mass transfer when displaying an image.

A display device provided according to some embodiments of the disclosure includes a circuit substrate and a plurality of light-emitting elements. The circuit substrate has an active region, wherein the active region includes a first region and a second region. The plurality of light-emitting elements are disposed on the circuit substrate, wherein the plurality of light-emitting elements include a first group of light-emitting elements corresponding to the first region and a second group of light-emitting elements corresponding to the second region, and a quantity of light-emitting elements of the first group of light-emitting elements is the same as a quantity of light-emitting elements of the second group of light-emitting elements. The first group of light-emitting elements includes a first light wavelength characteristic average value, the second group of light-emitting elements includes a second light wavelength characteristic average value, and an absolute value of a difference between the first light wavelength characteristic average value and the second light wavelength characteristic average value is less than or equal to 3 nm.

### BRIEF DESCRIPTION OF THE DRAWINGS

FIG. 1 is a schematic flowchart of a manufacturing method of a display device of an embodiment of the disclosure.

FIG. 2A is a partial top view of a display device of an embodiment of the disclosure.

FIG. 2B is a partial top view of an arrangement method of a plurality of light-emitting elements in the display device of the first embodiment of the disclosure.

FIG. 2C is a partial top view of an arrangement method of a plurality of light-emitting elements in the display device of the second embodiment of the disclosure.

FIG. 2D is a partial top view of an arrangement method of a plurality of light-emitting elements in the display device of the third embodiment of the disclosure.

FIG. 2E is a partial top view of an arrangement method of a plurality of light-emitting elements in the display device of the fourth embodiment of the disclosure.

### DESCRIPTION OF THE EMBODIMENTS

Reference will now be made in detail to the exemplary embodiments of the disclosure, and examples of the exemplary embodiments are illustrated in the accompanying drawings. Wherever possible, the same reference numerals are used in the figures and the descriptions to refer to the same or similar portions.

The disclosure may be understood by referring to the following detailed description in combination with the accompanying drawings. It should be noted that in order to make it easy for readers to understand and for the simplicity of the drawings, many of the drawings in the disclosure depict portions of an electronic device, and certain elements in the drawings are not drawn to actual scale. In addition, the number and the size of elements in the figures are for illustration and are not intended to limit the scope of the disclosure. The drawings should not be interpreted as defining or limiting the scope or the nature encompassed by the embodiments.

Throughout the disclosure, certain words are used to refer to specific elements in the specification and the claims. Those skilled in the art should understand that electronic device manufacturers may refer to the same elements by different names. The specification does not intend to distinguish between elements having the same function but different names. In the specification below and the claims, words such as “include”, “contains”, and “have” are open-ended words, so they should be interpreted to mean “containing but not limited to . . . ” Therefore, when the terms “including”, “containing”, and/or “having” are used in the specification of the disclosure, they specify the presence of the corresponding features, areas, steps, operations, and/or members. However, the presence of one or a plurality of corresponding features, areas, steps, operations, and/or members is not excluded.

The directional terms mentioned herein, such as “upper”, “lower”, “front”, “rear”, “left”, “right”, etc., refer to the directions of the drawings. Accordingly, the directional terms used are illustrative, not limiting, of the disclosure.

When a corresponding member (such as a layer or an area) is referred to as being “on another member”, it may be directly on the another member, or other members may be present between the two members. In addition, when a member is referred to as “on another member”, the two members have a top-down relationship in the top view direction, and the member may be above or below the another member, and the relationship depends on the orientation of the device.

The terms “equal to” or “the same”, “substantially”, or “essentially” are generally interpreted as within 20% of the given value or range, or interpreted as within 10%, 5%, 3%, 2%, 1%, or 0.5% of a given value or range.

Words such as “first” and “second” used in the specification and the claims are used to modify elements, which do not themselves imply and represent that the (or these) elements have any previous ordinal numbers, nor do they imply an order of a certain element with another element, or an order in manufacturing methods. These ordinal numbers are used to clearly distinguish an element having a certain designation from another element having the same designation. The same wording may be not used in the claims and the specification. Accordingly, the first member in the specification may be the second member in the claims.

It should be noted that, in the following embodiments, without departing from the spirit of the disclosure, features in several different embodiments may be replaced, reorganized, and mixed to complete other embodiments. As long as the features of the various embodiments do not violate the spirit of the disclosure or conflict each other, they may be mixed and matched arbitrarily.

The electrical connection described in the disclosure may both refer to direct connection or indirect connection. In the case of a direct connection, the terminals of elements on two circuits are connected directly or to each other by a conductor segment. In the case of indirect connection, there are switches, diodes, capacitors, inductors, other suitable elements, or a combination of the above elements between the terminals of the elements on the two circuits, but not limited thereto.

In the disclosure, length, width, and area may be measured using an optical microscope, but not limited thereto. In addition, any two values or directions used for comparison may have certain errors. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

An electronic device of the disclosure may include a display device, a light-emitting device, a sensing device, an antenna device, a touch device, a tiling device, or other suitable electronic devices, but not limited thereto. The electronic device may be a bendable, stretchable, foldable, rollable, and/or flexible electronic device, but not limited thereto. The display device may be applied to a notebook computer, a public display, a tiling display, an automotive display, a touch display, a transparent display, a double-sided display, a virtual reality display, an augmented reality display, a 3D display, a monochrome display, a color display, a television, a monitor, a mobile phone, a tablet computer, a light source module, a lighting equipment, and a military equipment. The sensing device may be a sensing device for detecting capacitance change, light, heat energy, or ultrasound, but not limited thereto. The sensing device may include a biometric sensor, a touch sensor, a fingerprint sensor, other suitable sensors, or a combination of the above types of sensors. It should be noted that the electronic device of the disclosure is taken as a display device as an example, but not limited thereto.

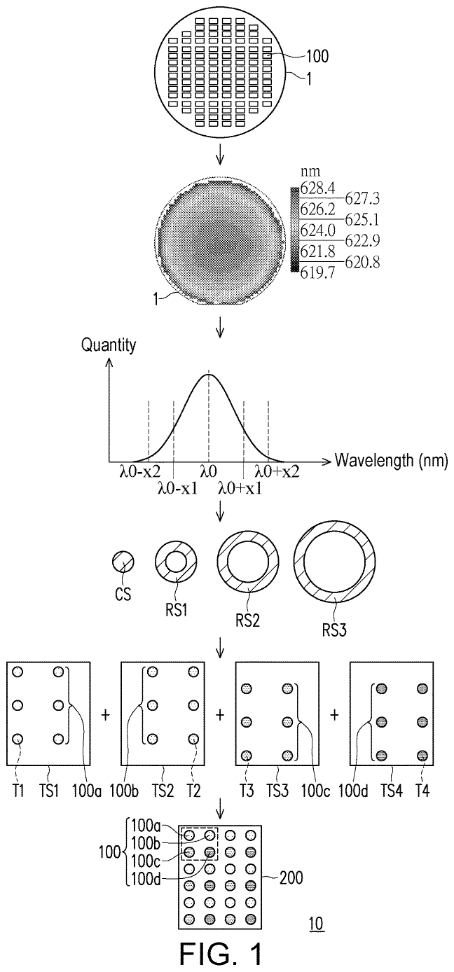

Referring to FIG. 1, the present embodiment provides a manufacturing method of a display device 10 including the following steps.
Step (1): provide an initial substrate 1, and the initial substrate 1 has a plurality of light-emitting elements 100 thereon.

In some embodiments, the initial substrate 1 may include a wafer, a carrier, or a chip for carrying and/or supporting a plurality of light-emitting elements, but not limited thereto. In the embodiment, the plurality of light-emitting elements 100 are micro LEDs, but not limited thereto. In other embodiments, the plurality of light-emitting elements 100 may include an OLED, a mini LED, or a QLED.
Step (2): measure the light wavelength characteristic value corresponding to each of the plurality of light-emitting elements 100.

In the embodiment, the measured light wavelength characteristic value of each of the plurality of light-emitting elements 100 may be a peak wavelength or a center wavelength. The peak wavelength may be defined as the wavelength corresponding to when the spectral luminous intensity or the radiant power of the light-emitting element 100 is highest. The central wavelength may be defined as the wavelength corresponding to a vertical line after the wavelength distribution in the spectrum diagram of the light-emitting element 100 is divided into two equal areas by the vertical line.

In some embodiments, an optical emission spectrometer may be used to measure the light wavelength characteristic values corresponding to each of the plurality of light-emitting elements 100. For example, the spectrum of each micro LED may be obtained via electroluminescence or photoluminescence to obtain the peak wavelength and/or the center wavelength of the corresponding micro LED.

Specifically, step (2) may make the plurality of light-emitting elements 100 carried on a specific region of the initial substrate 1 emit light via electroluminescence or photoluminescence, and sequentially measure the peak wavelength and/or the center wavelength of each of the light-emitting elements 100, but not limited thereto.
Step (3): divide the plurality of light-emitting elements 100 into a plurality of groups according to the corresponding light wavelength characteristic values, wherein the plurality of groups correspond to different light wavelength characteristic value intervals respectively.

In some embodiments, data of peak wavelengths and/or data of center wavelengths of the plurality of light-emitting elements 100 may present a normal distribution. Specifically, data of peak wavelengths and/or data of center wavelengths of the plurality of light-emitting elements 100 are distributed in a bell-shaped curve as shown in FIG. 1. Referring to FIG. 1, taking the data of the light wavelength characteristic values of the plurality of light-emitting elements 100 being divided into four groups as an example, in this bell-shaped curve, λ0 is the wavelength in which data appears most frequently in the light wavelength characteristic values of the plurality of light-emitting elements 100. Taking the light-emitting element 100 emitting red light as an example, λ0 may be any value between 615 nm and 635 nm, taking the light-emitting element 100 emitting green light as an example, λ0 may be any value between 525 nm and 545 nm, and taking the light-emitting element 100 emitting blue light as an example, λ0 may be any value between 450 nm and 470 nm. After λ0 is found, one or a plurality of wavelength differences may be designed according to requirements, such as a wavelength difference x2 and a wavelength difference x1, wherein the wavelength difference x1 is less than the wavelength difference x2. In some embodiments, light-emitting elements with light wavelength characteristic values between (λ0−x2) and (λ0+x2) may be retained, and light-emitting elements 100 with light wavelength characteristic values outside the range of (λ0−x2) and (λ0+x2) may be discarded, but not limited thereto. In some embodiments, (λ0+x2) is the light-emitting element 100 having the maximum light wavelength characteristic value, and (λ0−x2) is the light-emitting element 100 having the minimum light wavelength characteristic value. Taking the data of the light wavelength characteristic values of the plurality of light-emitting elements 100 as being divided into four groups as an example, the wavelength difference x2 may be greater than or equal to 2 nm and less than 5 nm, and the wavelength difference x1 may be greater than or equal to 1 nm and less than 3 nm, but not limited thereto. After λ0 is found and the wavelength difference x1 and the wavelength difference x2 are designed, five vertical lines passing through the wavelengths (λ0−x2), (λ0−x1), λ0, (λ0+x1), and (λ0+x2) may be drawn in the bell-shaped curve distribution shown in FIG. 1 to form the data of four groups of light wavelength characteristic value intervals, namely, the first group (λ0−x2) to (λ0−x1); the second group (λ0−x1) to 0; the third group λ0 to (λ0+x1); and the fourth group (λ0+x1) to (λ0+x2).

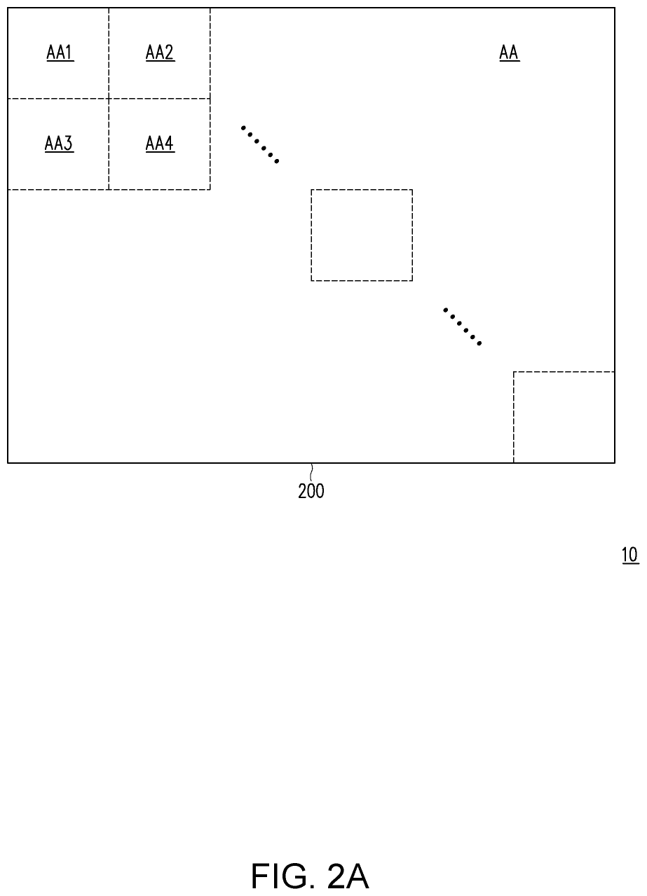

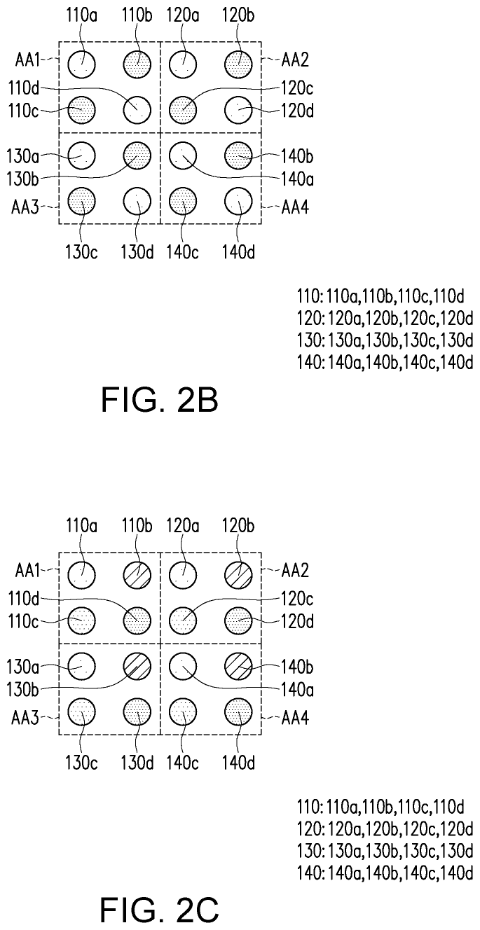

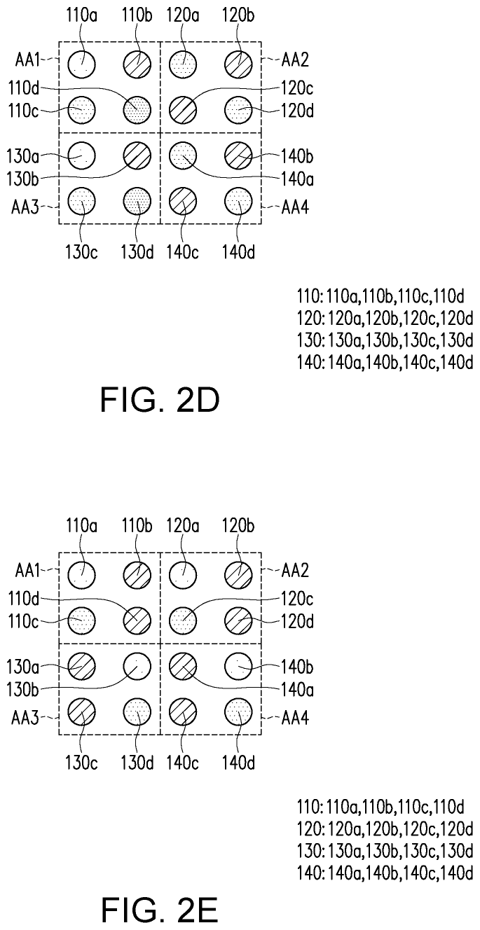

After the plurality of light-emitting elements 100 are divided into four groups according to the above method, the plurality of light-emitting elements 100 are transferred in bulk to the circuit substrate 200 to obtain the arrangement method of the plurality of light-emitting elements 100 as shown in FIG. 2C and FIG. 2D, but not limited thereto. In some embodiments, after the plurality of light-emitting elements 100 are divided into four groups in the manner described above, two groups (e.g., the first group and the fourth group, or the second group and the third group) are selected from the four groups and transferred in bulk to the circuit substrate 200 to obtain the arrangement method of the plurality of light-emitting elements 100 as shown in FIG. 2B, but not limited thereto.

In addition, a method of dividing the data of the light wavelength characteristic values of the plurality of light-emitting elements 100 into three groups is described below.

As described above, after λ0 of the plurality of light-emitting elements 100 is found and the wavelength difference x2 and the wavelength difference x1 are designed as needed, the light-emitting element 100 with the characteristic light wavelength value between (λ0−x2) and (λ0+x2) is retained. In the embodiment, the wavelength difference x1 may be greater than or equal to 1 nm and less than 3 nm, and the wavelength difference x2 may be greater than or equal to 2 nm and less than 4 nm, but not limited thereto. Then, four vertical lines passing through the wavelengths of (λ0−x2), (λ0−x1), (λ0+x1), and (λ0+x2) are drawn from the bell-shaped curve distribution to form the data of three groups of light wavelength characteristic value intervals, namely, the first group (λ0−x2) to (λ0−x1); the second group (λ0−x1) to (λ0+x1); and the third group (λ0+x1) to (λ0+x2), but not limited thereto.

After the plurality of light-emitting elements 100 are divided into three groups according to the above method, the plurality of light-emitting elements 100 are transferred in bulk to the circuit substrate 200 to obtain the arrangement method of the plurality of light-emitting elements 100 as shown in FIG. 2E, but not limited thereto.

In other embodiments, after λ0 of the plurality of light-emitting elements 100 is found, one wavelength difference x2 is designed, and the plurality of light-emitting elements 100 are divided into two groups of data of light wavelength characteristic value intervals, namely the first group (λ0−x2) to λ0; the second group λ0 to (λ0+x2). After the plurality of light-emitting elements are divided into two groups according to the above method, they the plurality of light-emitting elements transferred in bulk to the circuit substrate 200 to obtain the arrangement method of two groups of light-emitting elements 100, but not limited thereto.

However, the grouping method of not limited to the above. In general, the grouping method may be adjusted according to needs, wherein the quantity of the light-emitting elements 100 corresponding to each group may be the same or different according to different grouping methods. For example, in some embodiments, the quantity of light-emitting elements in the first group (λ0−x2) to (λ0−x1); the second group (λ0−x1) to λ0; the third group λ0 to (λ0+x1); and the fourth group (λ0+x1) to (λ0+x2) are substantially equal. In other embodiments, the quantity of the light-emitting elements 100 in the first group (λ0−x2) to (λ0−x1); the fourth group (λ0+x1) to (λ0+x2) may be less than the quantity of the light-emitting elements 100 in the second group (λ0−x1) to λ0; the third group λ0 to (λ0+x1). Since the first and the fourth groups have fewer light-emitting elements, some regions of an active region AA of the circuit substrate 200 may include the second and the third groups, as shown in FIG. 2B.

It is worth noting that the quantity of groups in the disclosure may be adjusted according to needs. In some embodiments, the quantity of the plurality of groups into which the plurality of light-emitting elements 100 are divided may be greater than or equal to 2 and less than or equal to 8.
Step (4): transfer the light-emitting elements 100 corresponding to each of the plurality of groups respectively.

After step (3) is completed, a plurality of groups of the light-emitting elements 100 having different light wavelength characteristic value intervals may be obtained. In some embodiments, the light-emitting elements 100 on the initial substrate 1 may be picked up respectively via a transfer stamp or other suitable transfer methods to be divided into a plurality of groups. At least one transfer stamp may be used to respectively transfer the plurality of groups of the light-emitting elements 100. The transfer stamp has a specific shape (e.g. an annular, circular, or other suitable shape) to select the light-emitting elements 100 having a plurality of groups of light wavelength characteristic value intervals. For example, referring to FIG. 1, the light wavelength characteristic values corresponding to the plurality of micro LEDs are greater the further away from the center position of the initial substrate 1 in a radial manner. Accordingly, taking the data of the light wavelength characteristic values of the plurality of light-emitting elements 100 being divided into four groups as an example, one circular transfer stamp CS and three annular transfer stamps RS1, RS2, and RS3 may be provided. In some embodiments, the circumference of the circular transfer stamp CS and the outer circumference of the annular transfer stamps RS1 and RS2 match the inner circumference of the annular transfer stamps RS1, RS2, and RS3, respectively. Accordingly, the first through fourth groups of light-emitting elements may be transferred via the circular transfer stamp CS and three annular transfer stamps RS1, RS2, and RS3, respectively, thereby achieving the object of dividing the data of the light wavelength characteristic values of the plurality of light-emitting elements 100 into four groups.

In some embodiments, the plurality of light-emitting elements 100 may be transferred to a corresponding intermediate substrate using a mass transfer technique. The mass transfer may be fluidic self-assembly, stamp transfer, laser transfer, electrostatic transfer, roll transfer, piezoelectric transfer, other suitable transfer methods, or a combination of transfer methods. In the embodiment, after the transfer stamp respectively picks up the plurality of light-emitting elements on the initial substrate 1 to be divided into a plurality of groups, the plurality of groups of light-emitting elements 100 are respectively transferred to the corresponding intermediate substrate via a fluid transfer technique, wherein the fluid transfer technique may include the following steps, but not limited thereto.
Step (a): provide a transfer box containing an intermediate substrate.

In the embodiment, a liquid for carrying the plurality of light-emitting elements 100 may be injected into the transfer box, and the intermediate substrate has a plurality of target positions, wherein the target positions may be assembly grooves into which the light-emitting elements 100 fall. Therefore, the quantity of the plurality of light-emitting elements 100 placed in the transfer box may be controlled according to the quantity of target positions on the intermediate substrate. For example, the quantity of the plurality of light-emitting elements 100 placed in the transfer box may be greater than the quantity of target positions on the intermediate substrate, so as to ensure that each target position on the intermediate substrate may receive the light-emitting elements 100.
Step (b): inject the liquid carrying the plurality of light-emitting elements 100 into the transfer box.

In the embodiment, the liquid carrying the plurality of light-emitting elements 100 may be placed in a pre-box first, and then injected into the transfer box via a pipeline connected to the pre-box and the transfer box, but not limited thereto.

In the embodiment, the plurality of light-emitting elements 100 flowing over the target positions of the intermediate substrate may be subject to a sucking effect and fall into the target positions to complete the transfer. After confirming that the light-emitting elements 100 have fallen into each target position on the intermediate substrate, the transfer of the group of light-emitting elements 100 to the corresponding intermediate substrate is completed.
Step (c): take out the intermediate substrate.

In the embodiment, the liquid in the transfer box may be drained first, and then the intermediate substrate may be taken out via a robot arm. Then, the intermediate substrate may be placed in a drying device to ensure liquid removal, but not limited thereto.
Step (d): repeat step (a) to step (c) to complete the transfer of the plurality of groups of light-emitting elements 100 to the corresponding intermediate substrate.

Please refer to FIG. 1. In the embodiment, the data of the light wavelength characteristic values of the plurality of light-emitting elements 100 are divided into four groups. Therefore, a first through a fourth groups of light-emitting elements 100a, 100b, 100c, and 100d are respectively transferred onto the intermediate substrates TS1, TS2, TS3, and TS4. In some embodiments, the intermediate substrates TS1, TS2, TS3, and TS4 include pluralities of target positions T1, T2, T3 and T4, respectively.

In the embodiment, when the intermediate substrates TS1, TS2, TS3, and TS4 are overlapped with each other in the vertical direction, the pluralities of target positions T1, T2, T3, and T4 are not overlapped with each other, and the projections of the target positions T1, T2, T3, and T4 adjacent to each other in the vertical direction may form a group of target positions of an array, such as a 2×2 array, but not limited thereto.

In other embodiments, after the data of the light wavelength characteristic values of the plurality of light-emitting elements 100 are divided into four groups, four transfer processes may be sequentially performed to transfer the first through fourth groups of light-emitting elements 100a, 100b, 100c, and 100d to the same intermediate substrate. The intermediate substrate includes the pluralities of target positions T1, T2, T3, and T4, which are not overlapped with each other, and may, when adjacent, form a group of target positions of an array.
Step (5): provide a circuit substrate, and transfer the plurality of groups of light-emitting elements 100 onto the circuit substrate.

In some embodiments, the circuit substrate 200 may include a base (not shown) and an element layer (not shown), but not limited thereto. The material of the base may be glass, plastic, quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), or other suitable materials or a combination of the above materials. The element layer is disposed on the base, and may include an electrical connection structure and an electronic element, but not limited thereto. The electrical connection structure provides a conductive transmission path for electrically connecting the light-emitting elements 100 transferred onto the circuit substrate 200 thereto. The electronic element includes a passive element and an active element, such as a transistor, a capacitor, a resistor, an inductor, a diode, a sensor, etc. In some embodiments, the electronic element is electrically connected to the light-emitting elements 100 transferred onto the circuit substrate 200.

In some embodiments, the plurality of groups of light-emitting elements 100 may be transferred onto the circuit substrate 200 via a mass transfer technique, but not limited thereto. Since the target position of each of the intermediate substrate TS1, TS2, TS3, and TS4 has the above setting relationship, the light-emitting elements 100a, 100b, 100c, and 100d transferred onto the circuit substrate may be divided into an arrangement method of a group of arrays.

In the embodiment, the light-emitting elements 100a, 100b, 100c, and 100d may be light-emitting elements corresponding to different light wavelength characteristic value intervals but emitting light of the same color, for example, all are light-emitting elements emitting red light, green light, or blue light, but not limited thereto.

By repeating the above step (1) to step (5), corresponding light-emitting elements 100 emitting light of different colors (e.g., red light, green light, and blue light) may be formed on the circuit substrate.

Referring to FIG. 2A, in the embodiment, the circuit substrate 200 has the active region AA and a peripheral region (not shown), wherein the peripheral region may be adjacent to at least one side of the active region AA. The active region AA may include a plurality of regions, wherein each region may include the same quantity of pixels, and each pixel may include a corresponding quantity of sub-pixels emitting light of different colors, but not limited thereto. For example, the active region AA may include a first region AA1 and a second region AA2 adjacent to the first region AA1. The first region AA1 and the second area AA2 may include four pixels respectively, and each pixel may include three sub-pixels emitting light of different colors (e.g., red light, green light, and blue light), but the disclosure is not limited thereto. In some embodiments, the active region AA may further include a third region AA3 and a fourth region AA4.

Please refer to FIG. 2A and FIG. 2B simultaneously. The plurality of light-emitting elements 100 are disposed on the circuit substrate 200. In the embodiment, the plurality of light-emitting elements 100 include the first group of light-emitting elements 110 corresponding to the first region AA1 and the second group of light-emitting elements 120 corresponding to the second region AA2, and the quantity of light-emitting elements of the first group of light-emitting elements 110 and the second group of light-emitting elements 120 is the same. In some embodiments, the first group of light-emitting elements 110 and the second group of light-emitting elements 120 are arranged in the same manner. In the embodiment, the first group of light-emitting elements 110 and the second group of light-emitting elements 120 are used to provide light of the same color. As FIG. 2B illustrates, since the regions AA1 and AA2 both include four pixels, the quantity of light-emitting elements of the first group of light-emitting elements 110 and the second group of light-emitting elements 120 are both four, wherein the four light-emitting elements may all be light-emitting elements emitting red light, green light, or blue light, but not limited thereto. In addition, in some embodiments, the plurality of light-emitting elements 100 may further include a third group of light-emitting elements 130 corresponding to the third region AA3 and a fourth group of light-emitting elements 140 corresponding to the fourth region AA4.

It is worth noting that, although each region of the active region AA includes a 2×2 array of light-emitting elements, but not limited thereto. In other embodiments, each region of the active region AA may include a group of light-emitting elements in other arrangements, and any two regions may be arranged in the same manner. Other arrangement methods may include a 3×3 array arrangement, a 4×4 array arrangement, a mosaic arrangement, a triangle arrangement, or other suitable arrangement methods.

In the embodiment, the first group of light-emitting elements 110 and the second group of light-emitting elements 120 are adjacent to each other. In some embodiments, the first group of light-emitting elements 110 includes a first light wavelength characteristic average value, and the second group of light-emitting elements 120 includes a second light wavelength characteristic average value, wherein the absolute value of the difference between the two is less than or equal to 1 nm. In the disclosure, after the light wavelength characteristic values of the plurality of light-emitting elements respectively corresponding to the first group of light-emitting elements 110 and the second group of light-emitting elements 120 on the circuit substrate 200 are measured via electroluminescence or photoluminescence, the above average of the light wavelength characteristic values are calculated to obtain the first light wavelength characteristic average value and the second light wavelength characteristic average value.

Based on the above, the light wavelength characteristic values of the plurality of light-emitting elements in the first group of light-emitting elements 110 and the second group of light-emitting elements 120 may be peak wavelengths and/or center wavelengths. In other words, the first light wavelength characteristic average value of the first group of light-emitting elements 110 may be the average value of the peak and/or center wavelengths of the plurality of light-emitting elements therein, and the second light wavelength characteristic average value of the second group of light-emitting elements 120 may be the average value of the peak and/or center wavelengths of the plurality of light-emitting elements therein. In the embodiment, by making the absolute value of the difference between the average values of the light wavelength characteristics of the first group of light-emitting elements 110 and the second group of light-emitting elements 120 adjacent to each other less than or equal to 1 nm, the just noticeable color difference (JNCD) is substantially less than or equal to 1, wherein the JNCD may be defined as the smallest unit of color difference that may be distinguished by human eyes. In this case, the phenomenon that the user observes uneven colors of adjacent display blocks of the display device may be reduced, thereby effectively alleviating the display quality issue.

It is worth noting that the absolute value of the difference between the average value of the light wavelength characteristics of the x-th group of light-emitting elements and the average value of the light wavelength characteristics of the y-th group of light-emitting elements in the other two non-adjacent regions in the active region AA is less than or equal to 3 nm, so that the JNCD may be substantially less than or equal to 3. In this case, the phenomenon that the user observes uneven colors of non-adjacent display blocks of the display device may be reduced, thereby effectively alleviating the display quality issue.

In the embodiment, two of the light-emitting elements of the first group of light-emitting elements 110 respectively have a first light wavelength characteristic value and a second light wavelength characteristic value, and the absolute value of the difference between the two is greater than the absolute value of the difference between the average value of the first light wavelength characteristic (e.g., the average of the light wavelength characteristic values of the plurality of light-emitting elements corresponding to the first group of light-emitting elements 110) and the average value of the second light wavelength characteristic (e.g., the average of the light wavelength characteristic values of the plurality of light-emitting elements corresponding to the second group of light-emitting elements 120). For example, referring to FIG. 2B, the first group of light-emitting elements 110 may include light-emitting elements 110a and light-emitting elements 110b, and the absolute value of the difference (e.g., the maximum difference) between the light wavelength characteristic values of the light-emitting elements 110a and 110b may be greater than or equal to 2 nm and less than 10 nm, but not limited thereto. In the embodiment, the light-emitting elements 110a belong to the first group of light wavelength characteristic value intervals ((λ0−x2) to (λ0−x1)); and the light-emitting elements 110b belong to the fourth group of light wavelength characteristic value intervals ((λ0+x1) to (λ0+x2)), but not limited thereto.

In some other embodiments, the absolute value of the difference (e.g., the maximum difference) between the light wavelength characteristic value of the light-emitting elements 110a and the light wavelength characteristic value of the light-emitting elements 110b is greater than or equal to 1 nm and less than 6 nm. For example, the light-emitting elements 110a belong to the second group of light wavelength characteristic value intervals ((λ0−x1) to λ0), and the light-emitting elements 110b belong to the third group of light wavelength characteristic value intervals (λ0 to (λ0+x1)).

Similarly, two of the light-emitting elements of the second group of light-emitting elements 120 respectively have two light wavelength characteristic values, and the absolute value of the difference between the two light wavelength characteristic values is greater than the absolute value of the difference between the first light wavelength characteristic average value and the second light wavelength characteristic average value. For example, referring to FIG. 2B, the second group of light-emitting elements 120 may include light-emitting elements 120a and light-emitting elements 120b, and the absolute value of the difference (e.g., the maximum difference) between the light wavelength characteristic values of the light-emitting elements 120a and 120b may be greater than or equal to 2 nm and less than 10 nm, but not limited thereto. In some other embodiments, the absolute value of the difference (e.g., the maximum difference) between the light wavelength characteristic values of the light-emitting elements 120a and 120b may be greater than or equal to 1 nm and less than 6 nm.

In addition, in the embodiment, the light wavelength characteristic values of another two light-emitting elements of the first group of light-emitting elements 110 respectively have a third light wavelength characteristic value and a fourth light wavelength characteristic value, and the absolute value of the difference between the two is greater than or equal to 2 nm and less than 10 nm. In detail, the first group of light-emitting elements 110 also includes light-emitting elements 110c and light-emitting elements 110d, wherein the light-emitting elements 110c belong to the fourth group of light wavelength characteristic value intervals ((λ0+x1) to (λ0+x2)); and the light-emitting elements 110d belong to the first group of light wavelength characteristic value intervals ((λ0−x2) to (λ0−x1) ).

In addition, in some embodiments, one of the plurality of light-emitting elements located in all regions of the active region AA has a maximum light wavelength characteristic value, and another of the plurality of light-emitting elements located in all regions of the active region AA has a minimum light wavelength characteristic value. In the disclosure, the light wavelength characteristic values of the plurality of light-emitting elements 100 on the circuit substrate 200 may be measured via electroluminescence or photoluminescence to find out the maximum light wavelength characteristic value and the minimum light wavelength characteristic value of the plurality of light-emitting elements, but not limited thereto. In some embodiments, a high-resolution camera may be used to photograph the plurality of light-emitting elements 100 on the circuit substrate 200 first to determine in which regions of the active region AA the light-emitting elements with the maximum and minimum light wavelength characteristic values are located, and then the light wavelength characteristic values of the light-emitting elements in the corresponding regions are measured via electroluminescence or photoluminescence to find the maximum light wavelength characteristic value and the minimum light wavelength characteristic value of the plurality of light-emitting elements, but not limited thereto. In the embodiment, the difference between the maximum light wavelength characteristic value and the minimum light wavelength characteristic value is greater than the absolute value of the difference between the first light wavelength characteristic average value (e.g., the average of the light wavelength characteristic values of the plurality of light-emitting elements corresponding to the first group of light-emitting elements 110) and the second light wavelength characteristic average value (e.g., the average of the light wavelength characteristic values of the plurality of light-emitting elements corresponding to the second group of light-emitting elements 120), and the difference between the maximum light wavelength characteristic value and the minimum light wavelength characteristic value is greater than or equal to 4 nm. For example, the light-emitting elements having the maximum and minimum light wavelength characteristic values are located at the same or different regions of the active region AA. In some embodiments, one of the first group of light-emitting elements 110 in the first region AA1 may have a maximum light wavelength characteristic value, and one of the second group of light-emitting elements 120 in the second region AA2 may have a minimum light wavelength characteristic value, but not limited thereto. In the embodiment, by making the difference between the maximum light wavelength characteristic value and the minimum light wavelength characteristic value greater than or equal to 4 nm, a plurality of light-emitting elements on the initial substrate may be used up as much as possible during the mass transfer process, thereby improving the utilization rate of the plurality of light-emitting elements on the initial substrate.

Referring to FIG. 2C, the first to fourth groups of light-emitting elements 110, 120, 130, and 140 each include light-emitting elements (e.g., the light-emitting elements 110a, 120a, 130a, 140a) of the first group of light wavelength characteristic value intervals ((λ0−x2) to (λ0−x1)); light-emitting elements (e.g., the light-emitting elements 110b, 120b, 130b, 140b) of the second group of light wavelength characteristic value intervals ((λ0−x1) to λ0); light-emitting elements (e.g., the light-emitting elements 110c, 120c, 130c, 140c) of the third group of light wavelength characteristic value intervals (λ0 to (λ0+x1)); and light-emitting elements (e.g., the light-emitting elements 110d, 120d, 130d, 140d) of the fourth group of light wavelength characteristic value intervals ((λ0+x1) to (λ0+x2)). In some embodiments, the absolute value of the difference (e.g., the maximum difference) between the light wavelength characteristic values of light-emitting elements of two different groups corresponding to the same region may be greater than or equal to 2 nm and less than 10 nm.

Referring to FIG. 2D, in the embodiment, different groups of light-emitting elements correspond to light-emitting elements with different combinations of light wavelength characteristic value intervals. For example, the first group of light-emitting elements 110 and the third group of light-emitting elements 130 both include light-emitting elements (e.g., the light-emitting elements 110a, 130a) of the first group of light wavelength characteristic value intervals ((λ0−x2) to (λ0−x1)); light-emitting elements (e.g., the light-emitting elements 110b, 130b) of the second group of light wavelength characteristic value intervals ((λ0−x1) to λ0); light-emitting elements (e.g., the light-emitting elements 110c, 130c) of the third group of light wavelength characteristic value intervals (λ0 to (λ0+x1)); and light-emitting elements (e.g., the light-emitting elements 110d, 130d) of the fourth group of light wavelength characteristic value intervals ((λ0+x1) to (λ0+x2)). The second group of light-emitting elements 120 and the fourth group of light-emitting elements 140 each include light-emitting elements of the third group of light wavelength characteristic value interval (λ0 to (λ0+x1)); and light-emitting elements of the second group of light wavelength characteristic value interval ((λ0−x1) to λ0). In the embodiment, the active region AA may include a light-emitting element group with four groups of light wavelength characteristic value intervals and a light-emitting element group with two groups of light wavelength characteristic value intervals.

In some other embodiments, the first group of light-emitting elements 110 and the third group of light-emitting elements 130 may both include light-emitting elements of the first group of light wavelength characteristic value intervals ((λ0−x2) to (λ0−x1)); and light-emitting elements of the fourth group of light wavelength characteristic value intervals ((λ0+x1) to (λ0+x2)). The second group of light-emitting elements 120 and the fourth group of light-emitting elements 140 may both include light-emitting elements of the second group of light wavelength characteristic value interval ((λ0−x1) to λ0) and light-emitting elements of the third group of light wavelength characteristic value interval (λ0 to (λ0+x1)).

It is worth noting that the plurality of light-emitting elements corresponding to each region shown in FIG. 2B to FIG. 2D may be mixed and matched with each other, and are not limited to these arrangement methods. By mixing and matching with each other, the utilization rate of the plurality of light-emitting elements of each group of light wavelength characteristic value intervals may be effectively improved.

Referring to FIG. 2E, in the embodiment, three groups of data of optical wavelength characteristic value intervals are formed. In detail, the first to fourth groups of light-emitting elements 110, 120, 130, and 140 each include light-emitting elements (e.g., the light-emitting elements 110a, 120a, 130b, 140b) of the first group of light wavelength characteristic value intervals ((λ0−x2) to (λ0−x1)); light-emitting elements (e.g., the light-emitting elements 110b, 110d, 120b, 120d, 130a, 130c, 140a, 140c) of the second group of light wavelength characteristic value intervals ((λ0−x1) to (λ0+x1)); and light-emitting elements (e.g., the light-emitting elements 110c, 120c, 130d, 140d) of the third group of light wavelength characteristic value intervals ((λ0+x1) to (λ0+x2)). In some embodiments, the absolute value of the difference (e.g., the maximum difference) between the light wavelength characteristic values of two light-emitting elements of two different groups corresponding to the same region may be greater than or equal to 2 nm and less than 8 nm. For example, the absolute value of the difference (e.g., the maximum difference) between the characteristic wavelength values of the light-emitting elements 110a and 110b in the first group of light-emitting elements 110 is greater than or equal to 2 nm and less than 8 nm, but not limited thereto.

Based on the above, in some embodiments of the disclosure, by dividing the plurality of light-emitting elements into a plurality of groups according to the respective corresponding light wavelength characteristic values, the light-emitting elements corresponding to each group of the plurality of groups may be transferred onto the circuit substrate respectively, so that each region of the active region of the circuit substrate may correspond to at least two groups of light-emitting elements. In addition, the absolute value of the difference between the average values of the light wavelength characteristics of the two regions corresponding to the active region is designed to be less than or equal to 3 nm to effectively reduce the color unevenness of the display block and effectively alleviate the display quality issue.

In some other embodiments of the disclosure, one and another of the plurality of light-emitting elements located in all regions of the active region each have a maximum light wavelength characteristic value and a minimum light wavelength characteristic value, and the difference between the maximum light wavelength characteristic value and the minimum light wavelength characteristic value is allowed to be designed to be greater than or equal to 4 nm. Therefore, when transferring the plurality of groups of light-emitting elements onto the circuit substrate, the plurality of light-emitting elements on the initial substrate may be used as much as possible, thereby improving the utilization rate of the plurality of light-emitting elements on the initial substrate.

What is claimed is:

1. A manufacturing method of a display device, comprising:
providing an initial substrate, wherein the initial substrate has a plurality of light-emitting elements thereon;
measuring a light wavelength characteristic value corresponding to each of the plurality of light-emitting elements;
dividing the plurality of light-emitting elements into a plurality of groups according to the corresponding light wavelength characteristic value, wherein the plurality of groups correspond to different light wavelength characteristic value intervals respectively;
transferring the light-emitting elements corresponding to each of the plurality of groups respectively; and
providing a circuit substrate, and transferring the plurality of groups of light-emitting elements onto the circuit substrate.

2. The manufacturing method of the display device of claim 1, wherein the step of transferring the light-emitting elements corresponding to each of the plurality of groups comprises:
picking up the light-emitting elements on the initial substrate respectively via a transfer stamp to be divided into the plurality of groups.

3. The manufacturing method of the display device of claim 2, further comprising:
transferring each of the light-emitting elements picked up via the transfer stamp to each intermediate substrate via a fluid transfer technique.

4. The manufacturing method of the display device of claim 2, wherein the transfer stamp comprises a circular transfer stamp and at least one annular transfer stamp.

5. The manufacturing method of the display device of claim 1, wherein a quantity of the plurality of groups is greater than or equal to 2 and less than or equal to 8.

6. The manufacturing method of the display device of claim 1, wherein the plurality of light-emitting elements comprise a first group of light-emitting elements and a second group of light-emitting elements, and an absolute value of a difference between an average value of first light wavelength characteristics of the first group of light-emitting elements and an average value of second light wavelength characteristics of the second group of light-emitting elements is less than or equal to 3 nm.

7. The manufacturing method of the display device of claim 1, wherein one of the light-emitting elements and another light-emitting element each have a maximum light wavelength characteristic value and a minimum light wavelength characteristic value, and a difference between the maximum light wavelength characteristic value and the minimum light wavelength characteristic value is greater than or equal to 4 nm.

8. The manufacturing method of the display device of claim 1, wherein the light wavelength characteristic value measured for each of the plurality of light-emitting elements comprises a peak wavelength and/or a center wavelength.

9. The manufacturing method of the display device of claim 1, wherein the light wavelength characteristic value corresponding to each of the plurality of light-emitting elements is greater the further away from a center position of the initial substrate.

10. A display device, comprising:
a circuit substrate having an active region, wherein the active region comprises a first region and a second region; and
a plurality of light-emitting elements disposed on the circuit substrate, wherein the plurality of light-emitting elements comprise a first group of light-emitting elements corresponding to the first region and a second group of light-emitting elements corresponding to the second region, and a quantity of light-emitting elements of the first group of light-emitting elements is the same as a quantity of light-emitting elements of the second group of light-emitting elements,
wherein the first group of light-emitting elements comprises a first light wavelength characteristic average value, the second group of light-emitting elements comprises a second light wavelength characteristic average value, and an absolute value of a difference between the first light wavelength characteristic average value and the second light wavelength characteristic average value is less than or equal to 3 nm.

11. The display device of claim 10, wherein the first group of light-emitting elements and the second group of light-emitting elements are configured to provide a light of a same color.

12. The display device of claim 10, wherein the first region is adjacent to the second region, and an absolute value of a difference between an average value of the first light wavelength characteristic and an average value of the second light wavelength characteristic is less than or equal to 1 nm.

13. The display device of claim 10, wherein two of the light-emitting elements of the first group of light-emitting elements respectively have a first light wavelength characteristic value and a second light wavelength characteristic value, and an absolute value of a difference between the first light wavelength characteristic value and the second light wavelength characteristic value is greater than the absolute value of the difference between the first light wavelength characteristic average value and the second light wavelength characteristic average value.

14. The display device of claim 13, wherein the absolute value of the difference between the first light wavelength characteristic value and the second light wavelength characteristic value is greater than or equal to 2 nm and less than 10 nm.

15. The display device of claim 13, wherein light wavelength characteristic values of another two light-emitting elements of the first group of light-emitting elements respectively have a third light wavelength characteristic value and a fourth light wavelength characteristic value, and an absolute value of a difference between the third light wavelength characteristic value and the fourth light wavelength characteristic value is greater than or equal to 2 nm and less than 10 nm.

16. The display device of claim 13, wherein light wavelength characteristic values of another two light-emitting elements of the first group of light-emitting elements respectively have a third light wavelength characteristic value and a fourth light wavelength characteristic value, and a difference between the third light wavelength characteristic value and the fourth light wavelength characteristic value is greater than or equal to 1 nm and less than 6 nm.

17. The display device of claim 13, wherein two of the light-emitting elements of the second group of light-emitting elements respectively have a fifth light wavelength characteristic value and a sixth light wavelength characteristic value, and a difference between the fifth light wavelength characteristic value and the sixth light wavelength characteristic value is greater than or equal to 2 nm and less than 10 nm.

18. The display device of claim 13, wherein two of the light-emitting elements of the second group of light-emitting elements respectively have a fifth light wavelength characteristic value and a sixth light wavelength characteristic value, and a difference between the fifth light wavelength characteristic value and the sixth light wavelength characteristic value is greater than or equal to 1 nm and less than 6 nm.

19. The display device of claim 13, wherein the first light wavelength characteristic value and the second light wavelength characteristic value each comprise a peak wavelength and/or a center wavelength.

20. The display device of claim 10, wherein one of the plurality of light-emitting elements has a maximum light wavelength characteristic value, and another of the plurality of light-emitting elements has a minimum light wavelength characteristic value, wherein a difference between the maximum light wavelength characteristic value and the minimum light wavelength characteristic value is greater than the absolute value of the difference between the first light wavelength characteristic average value and the second light wavelength characteristic average value, and the difference between the maximum light wavelength characteristic value and the minimum light wavelength characteristic value is greater than or equal to 4 nm.
